(19) United States
(12) Patent Application Publication
(10) Pub. No.: US 2008/0238750 A1
(43) Pub. Date: Oct. 2, 2008

(54) Intelligent Power Control Peripheral

(75) Inventors: Bryan Kris, Phoenix, AZ (US); Keith Curtis, Gilbert, AZ (US)

Correspondence Address: Attn: Paul N. Katz;Baker Botts L.L.P., One Shell Plaza, 910 Louisiana Street, Houston, TX, 77002-4995, US

(73) Assignee: MICROCHIP TECHNOLOGY INCORPORATED

(21) Appl. No.: 11/693,239

(22) Filed: Mar. 29, 2007

(51) Int. Cl. H03M 1/12

(52) U.S. Cl. 341/155

(57) ABSTRACT

An intelligent power control peripheral (IPCP) may facilitate communications among individual peripherals independent from a digital processor. The IPCP is a “Meta-Peripheral” that may incorporate a configurable inter-peripheral module communications network with digital pulse width modulation (PWM) generators and timing logic therefore, at least one ADC, analog comparators and at least one DAC that may be configured to provide an automatic power control structure that may also provide automatic digital processor/DSP task and workload scheduling for applications such as switch mode power supply (SMPS), brushed motor, etc. This Meta-Peripheral may further use a configurable control fabric in combination with the aforementioned specialized peripherals for the utmost in control configuration flexibility.

### TECHNICAL FIELD

The present disclosure relates to digital processors having an intelligent power control peripheral, and more particularly, to an intelligent power control peripheral that provides communications among individual peripherals, e.g., analog-to-digital converter (ADC), pulse width modulation (PWM) generator, analog comparator, digital-to-analog converter (DAC), etc., independent of the digital processor.

### BACKGROUND

There are many digital processors having digital signal processing (DSP) capabilities and stand alone peripheral devices such as analog-to-digital converter (ADC), pulse width modulation (PWM) generator, analog comparator, digital-to-analog converter (DAC), etc. But all of these peripheral devices require that software running on the processor/DSP be involved in coordinating all of the behavior of these separate peripherals. This coordination by the digital processor requires that significant processor resources be expended on scheduling and coordination thereof rather then on the task of actually controlling a process, e.g., switch mode power supply (SMPS), brushed motor, etc. For example, because processor control, using a software program running in the processor, is required to intervene in the operation of the peripheral devices, support for current mode control in SMPS applications is not feasible. Current mode control requires that the control system respond very quickly to changing conditions, e.g., voltage and/or current. Current mode control requires pulse width modulation (PWM) responses within nanoseconds.

### SUMMARY

Therefore there is need for ways to overcome the above-identified problems as well as other shortcomings and deficiencies of existing technologies by providing communications among individual peripherals, e.g., ADC, PWM generator, analog comparator, DAC, etc., necessary for high speed current control in SMPS applications that are independent from a digital processor. According to teachings of this disclosure, an intelligent power control peripheral (IPCP) may provide (e.g., facilitate) communications among the individual peripherals independent from the digital processor. The IPCP may be used for critical timing control of SMPS systems, brushed motor control, and a host of other applications. The IPCP is a “Meta-Peripheral” that may incorporate a configurable inter-peripheral module communications network with digital PWM generators and timing logic therefore, at least one ADC, analog comparators and at least one DAC that may be configured to provide an automatic power control structure that may also provide automatic digital processor/DSP task and workload scheduling. This Meta-Peripheral may further use a configurable control fabric in combination with the aforementioned specialized peripherals for the utmost in control configuration flexibility.

According to a specific example embodiment of this disclosure, an intelligent power control peripheral may comprise: an analog-to-digital converter (ADC) having a plurality of analog inputs and a plurality of sample and hold trigger inputs, wherein digital data outputs and interrupt outputs from the ADC are available for coupling to digital inputs of a digital processor; a plurality of analog comparators; and a pulse width modulation (PWM) generation module, wherein the PWM generation module has digital inputs available for coupling to digital outputs of the digital processor; whereby the ADC, the plurality of analog comparators and the PWM generation module interact with each other without substantial intervention from the digital process.

According to another specific example embodiment of this disclosure, an intelligent power control peripheral may comprise: a digital processor; an analog-to-digital converter (ADC) having a plurality of analog inputs and a plurality of sample and hold trigger inputs, wherein digital data outputs and interrupt outputs from the ADC are coupled to digital inputs of the digital processor; a plurality of analog comparators; a pulse width modulation (PWM) generation module, wherein the PWM generation module has digital inputs are coupled to digital outputs of the digital processor; and an ADC sample trigger circuit coupled to the ADC for determining when to take analog samples; whereby the ADC, the plurality of analog comparators, the PWM generation module and ADC sample trigger interact with each other without intervention from the digital process.

### BRIEF DESCRIPTION OF THE DRAWINGS

A more complete understanding of the present disclosure thereof may be acquired by referring to the following description taken in conjunction with the accompanying drawings wherein:

FIG. 1 illustrates a schematic block diagram of an intelligent power control peripheral (IPCP) configured for controlling and transferring data and trigger signals between an analog-to-digital converter (ADC), analog comparators and a pulse width modulation (PWM) generation module, according to a specific example embodiment of this disclosure;

FIG. 2 illustrates a schematic block diagram of an IPCP configured with a single PWM generator coupled to a plurality of analog and digital devices, according to another specific example embodiment of this disclosure; and

FIG. 3 illustrates a schematic timing diagram of two PWM signals showing resource allocation scheduling of the ADC and digital processor in multiple independent control loops for controlling different power conversion circuits facilitated with the IPCP, according to the teachings of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of specific example embodiments are schematically illustrated. Like elements in the drawings will be represented by like numbers, and similar elements will be represented by like numbers with a different lower case letter suffix.

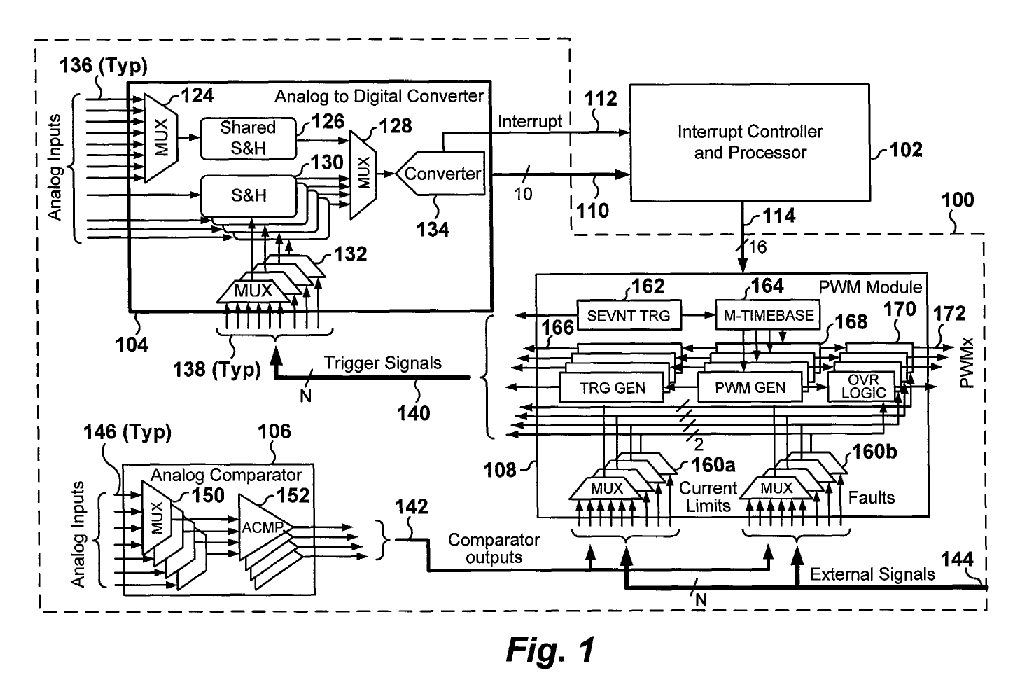

Referring to FIG. 1, depicted is a schematic block diagram of an intelligent power control peripheral (IPCP) configured for controlling and transferring data and trigger signals between an analog-to-digital converter (ADC), analog comparators and a pulse width modulation (PWM) generation module, according to a specific example embodiment of this disclosure. The IPCP, generally represented inside the dotted lines and by the numeral 100, comprises an ADC 104, analog comparators 106, and a PWM generation module 108. The IPCP 100 may be coupled to a digital processor 102 with a data-in bus 110, an interrupt bus 112 and a data-out bus 114. The digital processor 102 may receive input data on the data-in bus 110, interrupts on the interrupt bus 112, and send digital data on the data-out bus 114. The digital processor 102 may be a microprocessor, microcontroller, digital signal processor (DSP), programmable logic array (PLA), application specific integrated circuit (ASIC), etc. The IPCP and digital processor may be fabricated on a single semiconductor integrated circuit die (not shown). The IPCP 100 provides communication between the individual peripherals, e.g., ADC 104, analog comparators 106 and PWM generation module 108.

The ADC 104 may comprise a plurality of analog input channels 136 coupled to either a multiplexer 124 or a plurality of sample and hold circuits 130. The multiplexer 124 output may be coupled to a time shared sample and hold circuit 126. The plurality of sample and hold circuits 130 may be controlled by a plurality of trigger control multiplexers 132. The output of the time shared sample and hold circuit 126 and outputs of the plurality of sample and hold circuits 130 may be coupled to inputs of a multiplexer 128. The multiplexer 128 may be used to couple a selected one of its inputs to an internal analog to digital converter 134. The digitized data sample from the analog to digital converter 134 may be sent to the digital processor 102 over the data-in bus 110. The interrupt bus 112 may be used for indicating when conversion of the digitized data samples are valid. The data-in bus 110 and the interrupt bus 112 may be coupled to inputs of the digital processor 102, and the data-out bus 114 may be coupled to outputs of the digital processor 102.

The analog comparators 106 may be comprised of a plurality of analog input multiplexers 150 having outputs coupled to respective ones of a plurality of analog comparators 152. The plurality of analog comparators 152 outputs may be coupled to inputs of a plurality of digital multiplexers 160. The PWM generation module 108 may comprise a single event trigger (SEVNT TRG) 162, a master time base (M-TIMEBASE) 164, a plurality of trigger generators 166, a plurality of PWM generators (PWM GEN) 168, override (OVR) logic 170 having PWM outputs 172, and the plurality of digital multiplexers 160. The plurality of digital multiplexers 160 may receive digital inputs (e.g., logic 1 and 0, logic high and low, on and off, etc.) from the outputs 142 of the analog comparators 106 and/or from external signals 144. The IPCP 100 may also include scheduling timers, e.g., in the PWM module for timing, and comparator output logic changes to initiate and coordinate ADC and processor (e.g., software) tasks.

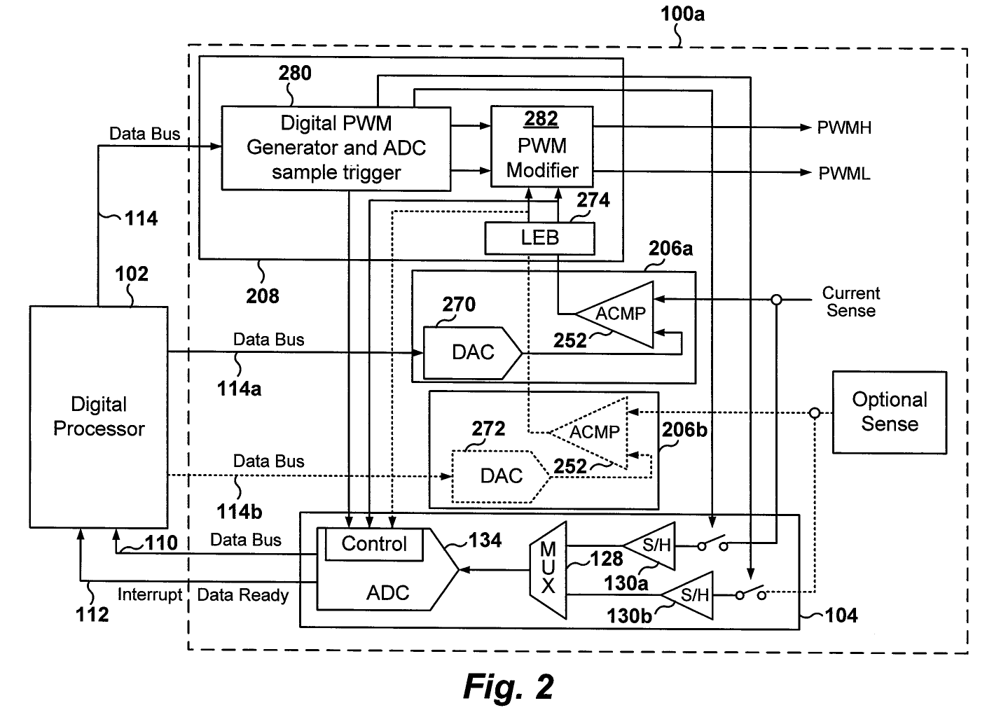

Referring to FIG. 2, depicted is a schematic block diagram of an IPCP configured with a single PWM generator coupled to a plurality of analog and digital devices, according to another specific example embodiment of this disclosure. The IPCP 100a may be configured with one PWM generator module 208 coupled to a plurality of analog comparators 252, and a control circuit for an analog-to-digital converter (ADC) 134. The configuration depicted in FIG. 2 is but one of many flexible configurations possible with the IPCP 100, according to the teachings of this disclosure. Additionally, the digital processor 102 may be coupled to DACs 270 and 272 over the data bus 114, and used to generate analog set points for the analog comparators 252. Current sense information and other (optional) sense information may be captured with the ADC 104 and sent to the digital processor 102 in digital form after being converted from analog to digital data. The PWM generator module 208 may comprise a digital PWM generation and ADC sample trigger 280, a PWM modifier circuit 282 and a leading edge blanking circuit 274. The IPCP 100a facilitates cooperation between the PWM generator module 208, the combination of analog comparators and DACs 206, and the analog sampling circuits of the ADC 104 without continuous intervention by the digital processor 102.

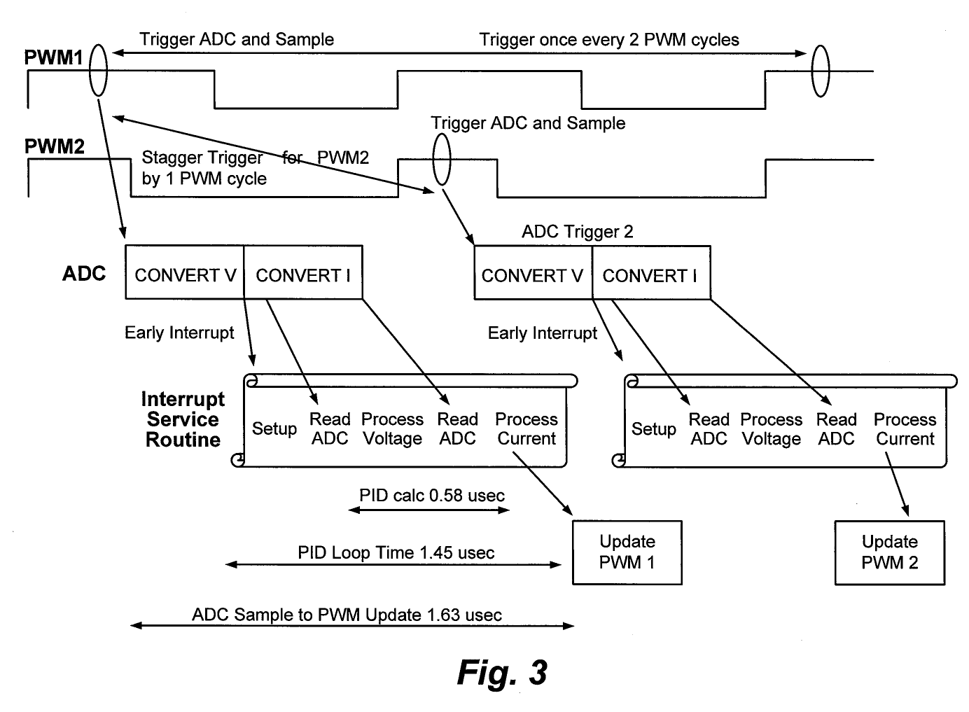

Referring to FIG. 3, depicted is a schematic timing diagram of two PWM signals showing resource allocation scheduling of the ADC and digital processor in multiple independent control loops for controlling different power conversion circuits facilitated with the IPCP, according to the teachings of this disclosure. The IPCP 100 may control operation during generation of PWM signals and feedback from sensor inputs. As shown in FIG. 3, the PWM1 signal triggers a first ADC that samples the voltage and current associated with the PWM1 control signal, and PWM2 triggers a second ADC that samples the voltage and current associated with the PWM2 control signal. After the voltage and current samples have been converted to digital data, interrupts are sent to the digital processor 102, wherein PID calculations are performed for desired voltage and current process control and the PWM1 and PWM2 signals are updated as required.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

1. An intelligent power control peripheral, comprising:
an analog-to-digital converter (ADC) having a plurality of analog inputs and a plurality of sample and hold trigger inputs, wherein digital data outputs and interrupt outputs from the ADC are available for coupling to digital inputs of a digital processor;
a plurality of analog comparators; and
a pulse width modulation (PWM) generation module, wherein the PWM generation module has digital inputs coupling coupled to digital outputs of the digital processor;
wherein the ADC, the plurality of analog comparators and the PWM generation module interact with the digital process as peripheral interfaces, whereby the digital processor controls at least one process through the peripheral interfaces.

2. The intelligent power control peripheral according to claim 1, wherein the ADC comprises:
a first multiplexer, wherein some of the plurality of analog inputs are coupled to inputs of the first multiplexer;
a shared first sample and hold circuit,
a plurality of second sample and hold circuits, wherein some other of the plurality of analog inputs are coupled to respective inputs of the plurality of second sample and hold circuits;
a plurality of second multiplexers having digital inputs adapted for coupling to trigger signal sources and outputs coupled to respective ones of the plurality of second sample and hold circuits for control thereof;
a second multiplexer having inputs coupled to outputs of the plurality of second sample and hold circuits and an output of the shared first sample and hold circuit; and
a converter circuit having an analog input coupled to an output of the second multiplexer, and digital outputs available for coupling to digital inputs of the digital processor.

3. The intelligent power control peripheral according to claim 1, wherein the plurality of analog comparators further comprise a plurality of third multiplexers having a plurality of analog inputs and outputs coupled to respective inputs of the plurality of analog comparators.

4. The intelligent power control peripheral according to claim 1, wherein the PWM generation module comprises:
a plurality of PWM generators;
a plurality of trigger generators having inputs coupled to respective ones of the plurality of PWM generators and outputs coupled to the ADC;
an event trigger circuit;
a master timebase coupled to the plurality of PWM generators and the event trigger circuit;
override (OVR) logic having inputs coupled to the plurality of PWM generators and outputs having PWM control signals thereon; and
a plurality of fourth multiplexers having some inputs available for coupling to external signals and some other inputs coupled to outputs of the plurality of analog comparators, and outputs coupled to the OVR logic.

5. The intelligent power control peripheral according to claim 4, wherein some of the external signals are current limit signals and some other of the external signals are fault signals.

6. The intelligent power control peripheral according to claim 1, further comprising scheduling timers to initiate ADC and digital processor tasks.

7. The intelligent power control peripheral according to claim 1, wherein the plurality of analog comparators initiate ADC and digital processor tasks.

8. The intelligent power control peripheral according to claim 1, further comprising the digital processor, the ADC, the plurality of analog comparators and the PWM generation module being fabricated on a single semiconductor integrated circuit die.

9. The intelligent power control peripheral according to claim 8, wherein the digital processor is selected from the group consisting of a microprocessor, a microcontroller, a digital signal processor (DSP), a programmable logic array (PLA), and an application specific integrated circuit (ASIC).

10. An intelligent power control peripheral, comprising:
a digital processor;
an analog-to-digital converter (ADC) having a plurality of analog inputs and a plurality of sample and hold trigger inputs, wherein digital data outputs and interrupt outputs from the ADC are coupled to digital inputs of the digital processor;
a plurality of analog comparators;
a pulse width modulation (PWM) generation module, wherein the PWM generation module has digital inputs are coupled to digital outputs of the digital processor; and
an ADC sample trigger circuit coupled to the ADC for determining when to take analog samples;
wherein the ADC, the plurality of analog comparators, the PWM generation module and ADC sample trigger interact with the digital processor as peripheral interfaces, whereby the digital processor controls at least one process through the peripheral interfaces.

11. The intelligent power control peripheral according to claim 10, wherein at least one of the plurality of analog comparators is used for current sensing.

12. The intelligent power control peripheral according to claim 10, further comprising at least one digital-to-analog converter (DAC) for generating an analog set point to an input of at least one of the plurality of analog comparators.

13. The intelligent power control peripheral according to claim 10, further comprising the digital processor, the ADC, the plurality of analog comparators, the PWM generation module and the ADC sample trigger circuit being fabricated on a single semiconductor integrated circuit die.

14. The intelligent power control peripheral according to claim 10, wherein the digital processor is selected from the group consisting of a microprocessor, a microcontroller, a digital signal processor (DSP), a programmable logic array (PLA), and an application specific integrated circuit (ASIC).
